(19) United States
(12) Patent Application Publication
(10) Pub. No.: US 2020/0315070 A1
(43) Pub. Date: Oct. 1, 2020

(54) AUXILIARY COOLING REDUNDANCY FOR COMPONENTS USING ACTUATING FAN PACK

(71) Applicant: LENOVO Enterprise Solutions (Singapore) PTE. LTD., New Tech Park (SG)

(72) Inventors: Jeffrey Scott Holland, Morrisville, NC (US); Bejoy Jose Kochuparambil, Apex, NC (US); Vinod Kamath, Raleigh, NC (US); Chunjian Ni, Cary, NC (US)

(21) Appl. No.: 16/370,711

(22) Filed: Mar. 29, 2019

(51) Int. Cl. H05K 7/20; F04D 25/16; F04D 29/60

(52) U.S. Cl. CPC H05K 7/20836; H05K 7/20736; F04D 29/601; H05K 7/20172; F04D 25/166; H05K 7/20145

(57) ABSTRACT

An apparatus for auxiliary cooling redundancy for components using an actuating fan pack includes a fan pack. The fan pack includes a fan positioned to provide a stream of air directed toward a component mounted in the server rack and the server rack includes components for a data system. The apparatus includes and a vertical drive configured to move the fan pack vertically to a position so air from the fan is directed toward the component. The apparatus includes a positioning controller configured to direct the vertical drive to move the fan pack to a front of a component in the server rack and configured to turn on the fans.

### FIELD

The subject matter disclosed herein relates to cooling components in a server rack and more particularly relates to cooling components using a movable fan pack.

### BACKGROUND

Often computer system components are mounted in server racks. Each rack-mounted component typically has a specified width, has a depth less than a maximum, and has a height that is an integer number of a rack unit. A rack-mounted component is typically designed to operate within a particular temperature range. However, due to failures, excessive loading, etc. temperatures within the component approach or exceed a specified maximum temperature. To compensate, often loading for the component is reduced or the component is rendered inoperable. Having each component rated for a particular range may be expensive compared to lower rated components. Often, rack-mounted computer equipment is rated for a particular temperature range even though most of the time the temperature of the rack-mounted component will only approach or exceed a maximum temperature limit occasionally or not at all unless the component fails.

### BRIEF SUMMARY

An apparatus for auxiliary cooling redundancy for components using an actuating fan pack includes a fan pack that includes a fan positioned to provide a stream of air directed toward a component mounted in the server rack and the server rack includes components for a data system. The apparatus includes a vertical drive configured to move the fan pack vertically to a position so air from the fan is directed toward the component. The apparatus includes a positioning controller configured to direct the vertical drive to move the fan pack to a front of a component in the server rack and configured to turn on the fans.

An apparatus for auxiliary cooling redundancy for components using an actuating fan pack includes a fan pack. The fan pack includes a plurality of fans each positioned to provide a stream of air directed toward a component mounted in the server rack. The server rack includes components for a data system. The apparatus includes a vertical drive configured to move the fan pack vertically to a position such that the stream of air from the fan is directed toward the component. The vertical drive includes one or more vertical guides coupled to the fan pack. The one or more vertical guides are configured to position the fan pack horizontally centered about a vertical axis in the center of a front of the server rack. The vertical drive includes a motor and a drive system configured to move the fan pack vertically in response to rotation of the motor.

A system for auxiliary cooling redundancy for components using an actuating fan pack includes a fan pack. The fan pack includes a fan positioned to provide a stream of air directed toward a component mounted in the server rack. The server rack includes components for a data system. The system includes a vertical drive configured to move the fan pack vertically to a position so air from the fan is directed toward the component, and a positioning controller. The positioning controller is configured to sense an ambient temperature where the server rack is located is above an ambient threshold, a temperature of the component is above a threshold, and/or a cooling fan of the component has reached a maximum cooling capacity. The positioning controller controls the vertical drive to move the fan pack to a position in front of the component and to turn on the fan of the fan pack.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1 is a schematic block diagram illustrating one embodiment of a system for auxiliary cooling redundancy for components using an actuating fan pack;

FIG. 2 is a schematic block diagram illustrating a front view and a side view of one embodiment of an apparatus for auxiliary cooling redundancy for components using an actuating fan pack;

FIG. 3 is a schematic block diagram illustrating a front view of another embodiment of an apparatus for auxiliary cooling redundancy for components using an actuating fan pack positioned between components;

FIG. 4 is a schematic block diagram illustrating a front view of an embodiment of an apparatus for auxiliary cooling redundancy for components using an actuating fan pack positioned to cool a two rack unit component;

FIG. 5 is a schematic block diagram illustrating a front view of an embodiment of an apparatus for auxiliary cooling redundancy for components with two actuating fan packs cooling two components;

FIG. 6 is a schematic block diagram illustrating a front view of an embodiment of an apparatus for auxiliary cooling redundancy for components using two actuating fan packs cooling a four rack unit component;

FIG. 7 is a schematic block diagram illustrating a partial side view of an embodiment of an apparatus for auxiliary cooling redundancy for components using an actuating fan pack with a pulley and spring lift system;

FIG. 8 is a schematic block diagram illustrating a partial side view of an embodiment of an apparatus for auxiliary cooling redundancy for components using an actuating fan pack with a pulley lift system;

FIG. 9 is a schematic block diagram illustrating a partial side view of an embodiment of an apparatus for auxiliary cooling redundancy for components using an actuating fan pack with a worm gear lift system;

FIG. 10 is a schematic block diagram illustrating a partial side view of an embodiment of an apparatus for auxiliary cooling redundancy for components using an actuating fan pack with louvers in two different positions;

FIG. 11 is a schematic block diagram illustrating a partial side view of an embodiment of an apparatus for auxiliary cooling redundancy for components using an actuating fan pack in a deployed state and in a retracted state; and

FIG. 12 is a schematic block diagram illustrating a partial side view of an embodiment of an apparatus for auxiliary cooling redundancy for components using two actuating fan packs in a deployed state and in a retracted state.

### DETAILED DESCRIPTION

As will be appreciated by one skilled in the art, aspects of the embodiments may be embodied as a system, method or program product. Accordingly, embodiments may take the form of an entirely hardware embodiment or an embodiment combining software (including firmware, resident software, micro-code, etc.) and hardware aspects that may all generally be referred to herein as a “circuit,” “controller” or “system.” Furthermore, embodiments may include portions with a program product embodied in one or more computer readable storage devices storing machine readable code, computer readable code, and/or program code, referred hereafter as code. The storage devices may be tangible, non-transitory, and/or non-transmission. The storage devices may not embody signals. In a certain embodiment, the storage devices only employ signals for accessing code.

Many of the functional units described in this specification have been labeled as controllers, in order to more particularly emphasize their implementation independence. For example, a controller may be implemented as a hardware circuit comprising custom VLSI circuits or gate arrays, off-the-shelf semiconductors such as logic chips, transistors, or other discrete components. A controller may also be implemented in programmable hardware devices such as field programmable gate arrays, programmable array logic, programmable logic devices or the like.

Controllers may also be implemented in code and/or software for execution by various types of processors. An identified controller of code may, for instance, comprise one or more physical or logical blocks of executable code which may, for instance, be organized as an object, procedure, or function. Nevertheless, the executables of an identified controller need not be physically located together, but may comprise disparate instructions stored in different locations which, when joined logically together, comprise the controller and achieve the stated purpose for the controller.

Indeed, a controller of code may be a single instruction, or many instructions, and may even be distributed over several different code segments, among different programs, and across several memory devices. Similarly, operational data may be identified and illustrated herein within controllers, and may be embodied in any suitable form and organized within any suitable type of data structure. The operational data may be collected as a single data set, or may be distributed over different locations including over different computer readable storage devices. Where a controller or portions of a controller are implemented in software, the software portions are stored on one or more computer readable storage devices.

Any combination of one or more computer readable medium may be utilized. The computer readable medium may be a computer readable storage medium. The computer readable storage medium may be a storage device storing the code. The storage device may be, for example, but not limited to, an electronic, magnetic, optical, electromagnetic, infrared, holographic, micromechanical, or semiconductor system, apparatus, or device, or any suitable combination of the foregoing.

More specific examples (a non-exhaustive list) of the storage device would include the following: an electrical connection having one or more wires, a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Code for carrying out operations for embodiments may be written in any combination of one or more programming languages including an object oriented programming language such as Python, Ruby, Java, Smalltalk, C++, or the like, and conventional procedural programming languages, such as the “C” programming language, or the like, and/or machine languages such as assembly languages. The code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise.

Furthermore, the described features, structures, or characteristics of the embodiments may be combined in any suitable manner. In the following description, numerous specific details are provided, such as examples of programming, software controllers, user selections, network transactions, database queries, database structures, hardware controllers, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

The description of elements in each figure may refer to elements of proceeding figures. Like numbers refer to like elements in all figures, including alternate embodiments of like elements.

As used herein, a list with a conjunction of “and/or” includes any single item in the list or a combination of items in the list. For example, a list of A, B and/or C includes only A, only B, only C, a combination of A and B, a combination of B and C, a combination of A and C or a combination of A, B and C. As used herein, a list using the terminology “one or more of” includes any single item in the list or a combination of items in the list. For example, one or more of A, B and C includes only A, only B, only C, a combination of A and B, a combination of B and C, a combination of A and C or a combination of A, B and C. As used herein, a list using the terminology “one of” includes one and only one of any single item in the list. For example, “one of A, B and C” includes only A, only B or only C and excludes combinations of A, B and C. As used herein, “a member selected from the group consisting of A, B, and C,” includes one and only one of A, B, or C, and excludes combinations of A, B, and C.” As used herein, “a member selected from the group consisting of A, B, and C and combinations thereof” includes only A, only B, only C, a combination of A and B, a combination of B and C, a combination of A and C or a combination of A, B and C.

An apparatus for auxiliary cooling redundancy for components using an actuating fan pack includes a fan pack includes a fan positioned to provide a stream of air directed toward a component mounted in the server rack and the server rack includes components for a data system. The apparatus includes a vertical drive configured to move the fan pack vertically to a position so air from the fan is directed toward the component. The apparatus includes a positioning controller configured to direct the vertical drive to move the fan pack to a front of a component in the server rack and configured to turn on the fans.

In some embodiments, components mounted in the server rack each have a vertical height that is an integer number of rack units and the fan pack has a vertical height of one at least rack unit (“1U”). In other embodiments, the fan pack includes a plurality of fans positioned horizontally across the fan pack. In other embodiments, the vertical drive includes one or more vertical guides that are configured to maintain the fan pack in a horizontal orientation on a front of the server rack. In other embodiments, the vertical drive includes a motor configured to move the fan pack up and/or down to a specified position. In other embodiments, the vertical drive includes one or more of a pulley, a cable, a worm gear, a spring, etc.

In some embodiments, the positioning controller is configured to sense an ambient temperature where the server rack is located is above an ambient threshold, a temperature of the component is above a threshold and/or a cooling fan of the component has reached a maximum cooling capacity. The positioning controller is configured to, based on the sensing, direct the vertical drive to move the fan pack to a position in front of the component and turns on the fan of the fan pack. In further embodiments, the positioning controller is configured to autonomously move the fan pack and turns on the fan of the fan pack in response to a heat management algorithm determining that heating of the component is above a threshold. In another further embodiment, the positioning controller is configured to move the fan pack and to turn on the fan in response to user input, input from a baseboard management controller and/or input from a data center management system.

In some embodiments, the fan pack is one of a plurality of fan packs. Each fan pack is separately operable to move vertically. In other embodiments, the vertical drive is configured to move the fan pack between two components to provide cooling to both components. In other embodiments, the fan pack includes an air direction device that is selectively positionable to control a spread of an air flow from the fan to direct the air flow directly to a component with a height of 1U, spread across a front of a component with a height greater than 1U, and/or spread across a front of two or more components. In other embodiments the vertical drive is configured to position the fan pack above and/or below the server rack during a period of non-use of the fan pack. In other embodiments, the position above the server rack is a position along a top side of the server rack and the position below the server rack is a position along a bottom side of the server rack.

An apparatus for auxiliary cooling redundancy for components using an actuating fan pack includes a fan pack. The fan pack includes a plurality of fans each positioned to provide a stream of air directed toward a component mounted in the server rack. The server rack includes components for a data system. The apparatus includes a vertical drive configured to move the fan pack vertically to a position such that the stream of air from the fan is directed toward the component. The vertical drive includes one or more vertical guides coupled to the fan pack. The one or more vertical guides are configured to position the fan pack horizontally about a vertical axis in the center of a front of the server rack. The vertical drive includes a motor and a drive system configured to move the fan pack vertically in response to rotation of the motor.

In some embodiments, the fan pack is a first fan pack and the apparatus includes a second fan pack mounted to the vertical guides and a second drive system configured to move the second fan pack vertically in response to rotation of the motor and/or a second motor. In other embodiments, the apparatus includes a positioning controller that senses that an ambient temperature where the server rack is located is above an ambient threshold, a temperature of the component is above a threshold, and/or a cooling fan of the component has reached a maximum cooling capacity. The positioning controller is configured to direct the vertical drive to move the fan pack to a position in front of the component and turns on the plurality of fans of the fan pack.

A system for auxiliary cooling redundancy for components using an actuating fan pack includes a fan pack. The fan pack includes a fan positioned to provide a stream of air directed toward a component mounted in the server rack. The server rack includes components for a data system. The system includes a vertical drive configured to move the fan pack vertically to a position so air from the fan is directed toward the component, and a positioning controller. The positioning controller is configured to sense an ambient temperature where the server rack is located is above an ambient threshold, a temperature of the component is above a threshold, and/or a cooling fan of the component has reached a maximum cooling capacity. The positioning controller is configured to control the vertical drive to move the fan pack to a position in front of the component and to turn on the fan of the fan pack.

In some embodiments, the positioning controller is configured to autonomously move the fan pack and to turn on the fan of the fan pack in response to a heat management algorithm determining that heating of the component is above a threshold. In other embodiments, the positioning controller is configured to move the fan pack and to turn on the fan in response to one or more of user input, input from a baseboard management controller and/or input from a data center management system.

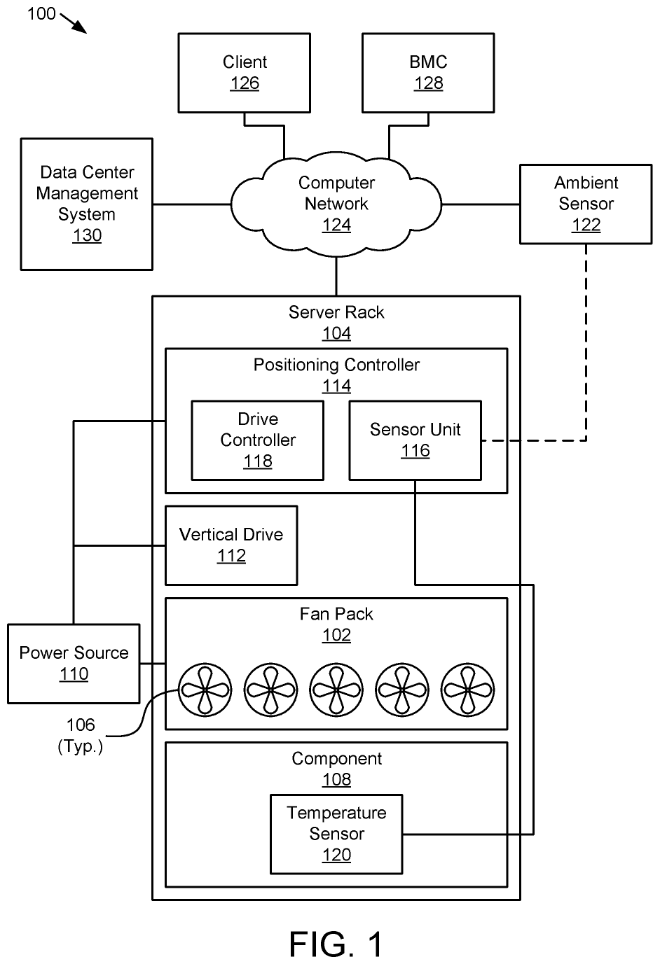

FIG. 1 is a schematic block diagram illustrating one embodiment of a system 100 for auxiliary cooling redundancy for components using an actuating fan pack 102. The fan pack 102, in some embodiments, spans a width of a front of a server rack 104. The fan pack 102 includes at least one fan 106 positioned to provide a stream of air directed toward a component 108 mounted in the server rack 104. In the depicted embodiment, the fan pack 102 includes five fans 106. Where the server rack 104 includes components 108 each with a vertical dimension that is an integer number of rack units (e.g. 1U, 2U, 4U, etc.), in some embodiments, the fan pack 102 is sized to be about 1U and the fans 106 are sized with a diameter that is about 1U. In some embodiments, a rack unit is 44.45 millimeters (“mm”). Fans 106 may be 40 mm or a similar size and may be chosen from standard fan sizes. The diameter of the fans 106 dictates a maximum number of fans 106 based on fan diameter and a server rack width. For a standard width server rack 104, one embodiment of a fan pack 102 includes 10 fans 106 that are 40 mm fans. One of skill in the art will recognize other configurations of fans 106 for a fan pack 102.

The server rack 104, in some embodiments, includes components 108 for a data system. For example, the server rack 104 is a standard rack sized for a data center and sized to accommodate rack mounted servers, storage devices, power supplies and other standard rack-mounted data components 108. In typical data center server racks 104, the components 108 are of a standard width and have a depth that is less than a maximum depth. The components 108 also have a height that is 1U, 2U, 3U, 4U, etc. and are mounted in the server rack 104 with a front of each component 108 facing a front of the server rack 104. Typically, air flows into the front of the components 108 and exits the back of the components 108. Often, a component 108 will include one or more internal fans to facilitate cooling of the component 108 and ambient air at the front of the server racks 104 is kept at a temperature so that the internal fans of the component 108 are capable of maintaining temperatures within the component 108 below one or more thresholds.

Cold air may be pumped into an isle where the fronts of server racks 104 are facing. A typical goal for a maximum temperature for ambient air in a cold isle is 27 degrees Celsius (“C”). The components 108 may be rated for an inlet temperature meeting an American Society of Heating, Refrigerating and Air-Conditioning Engineers (“ASHRAE”) A2, A3 or A4 specification of a temperature range where the A2 range is 5-35 degrees C., the A3 range is 5-40 degrees C., and the A4 range is 5-45 degrees C.

A component 108 meeting the ASHRAE A4 standard is typically more expensive than a component 108 meeting the ASHRAE A2 standard. A data center manager may be forced to buy more expensive components 108 where temperatures are expected to be above the ASHRAE A3 range but below the ASHRAE A4 range, even where the high temperatures are expected only in extreme circumstances. The fan pack 102 provides a solution that may allow a data center manager to buy a component 108 with a lower temperature rating where the data center manager can count on a cooling redundancy provided by the fan pack 102. Thus, the cost of a fan pack system may be less than the cost of more expensive components 108 with a higher temperature rating.

The system 100 also includes a power source 110 providing power to the fan 106 of the fan pack 102 and a vertical drive 112 that moves the fan pack 102 vertically to a position so air from the fan(s) 106 is directed toward the component 108. For example, when a component 108 is hot, the vertical drive 112 moves the fan pack 102 in front of the hot component 108 and the power source 110 provides power to the fan(s) 106 to provide additional cooling to the component 108.

In some embodiments, the system 100 includes a positioning controller 114 that directs the vertical drive 112 to move the fan pack 102 to a front of a component 108 in the server rack 104 and turns on the fans 106. In some embodiments, the positioning controller 114 controls the vertical drive 112 and power source 110 to move the fan pack 102 into a position to cool a component 108 and to turn on the one or more fans 106 of the fan pack 102. In some embodiments, the positioning controller 114 includes a sensor unit 116 that senses various conditions of the components 108 in the server rack 104. In some examples, the sensor unit 116 senses that an ambient temperature where the server rack 104 is located is above an ambient threshold, that a temperature of the component 108 is above a threshold, and/or a cooling fan of the component 108 has reached a maximum cooling capacity. For example, the sensor unit 116 may receive temperature data from a temperature sensor 120 in the component 108 or from an ambient temperature sensor 122 that senses ambient air temperature in the cold isle of the server rack 104 or other relevant location in the data center where the server rack 104 is located. The sensor unit 116 may receive temperature data through data channels of the server rack 104, through a computer network 124 connected to the server rack 104, etc.

The positioning controller 114, in some embodiments, includes a drive controller 118 that directs the vertical drive 112 to move the fan pack 102 to a position in front of a hot component 108 and turns on the fan 106 of the fan pack 102. The positioning controller 114, in some embodiments, determines from the sensor unit 116 a component 108 that needs additional cooling and communicates to the drive controller 118 which component 108 is too hot or expected to be too hot. The drive controller 118 then actuates the vertical drive 112 to move the fan pack 102 in position with respect to the hot component 108 and turns on the one or more fans 106 to start cooling the component 108.

In some embodiments, the positioning controller 114 autonomously moves the fan pack 102 and turns on the one or more fans 106 of the fan pack 102 in response to a heat management algorithm determining that heating of the component 108 is above a threshold. In some embodiments, the heat management algorithm uses information from the sensor unit 116. In other embodiments, the positioning controller 114 moves the fan pack 102 and turns on the one or more fans 106 in response to some external input. For example, the external input may be user input, for instance, through a client 126 connected to the server rack 104 through the computer network 124. In other embodiments, the external input is input from a baseboard management controller (“BMC”) 128 or input from a data center management system 130. In one example, a data center manager configures the BMC 128 and/or data center management system 130 to control the fan pack 102 either manually or based on some type of heat management algorithm. One of skill in the art will recognize other ways for the positioning controller 114 to control the fan pack 102 either automatically or based on external input.

The computer network 124, in some embodiments, include cabling to the server rack 104, such as optical fiber cables, wires, etc. and may be part of a local area network (“LAN”), wide area network (“WAN”), fiber optic network, the internet, and the like. In other embodiments, at least a portion of the network is wireless. In other embodiments, the computer network 124 includes more than one network type.

The wireless connection may be a mobile telephone network. The wireless connection may also employ a Wi-Fi network based on any one of the Institute of Electrical and Electronics Engineers (IEEE) 802.11 standards. Alternatively, the wireless connection may be a BLUETOOTH® connection. In addition, the wireless connection may employ a Radio Frequency Identification (RFID) communication including RFID standards established by the International Organization for Standardization (ISO), the International Electrotechnical Commission (IEC), the American Society for Testing and Materials® (ASTM®), the DASH7™ Alliance, and EPCGlobal™.

Alternatively, the wireless connection may employ a ZigBee® connection based on the IEEE 802 standard. In one embodiment, the wireless connection employs a Z-Wave® connection as designed by Sigma Designs®. Alternatively, the wireless connection may employ an ANT® and/or ANT+® connection as defined by Dynastream® Innovations Inc. of Cochrane, Canada.

The wireless connection may be an infrared connection including connections conforming at least to the Infrared Physical Layer Specification (IrPHY) as defined by the Infrared Data Association® (IrDA®). Alternatively, the wireless connection may be a cellular telephone network communication. All standards and/or connection types include the latest version and revision of the standard and/or connection type as of the filing date of this application.

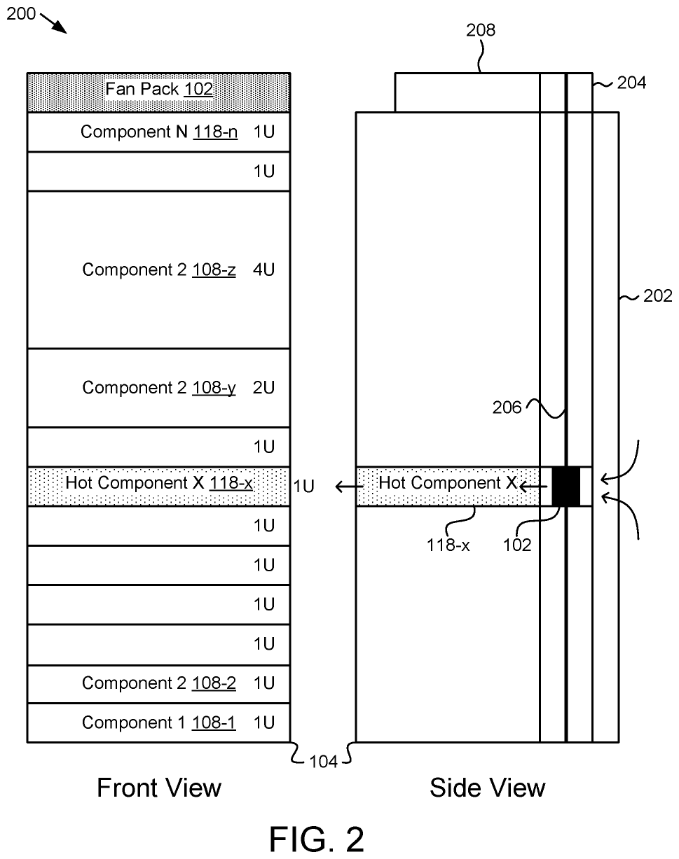

FIG. 2 is a schematic block diagram illustrating a front view and a side view of one embodiment of an apparatus 200 for auxiliary cooling redundancy for components using an actuating fan pack 102. The apparatus 200 includes a server rack 104 with n components 108-1, 108-2, . . . 108-n of various vertical heights. Some components 108 have a height of 2U and some have a height of 4U. In the apparatus 200 depicted in FIG. 2, one component 108-y has a height of 2U and one component 108-y has a height of 4U. Not all components are labeled and/or depicted for clarity. In addition, in some embodiments the server rack 104 includes wheels, legs, etc. under the rack (not shown).

For the front view, the fan pack 102 is depicted at the top of the server rack 104 and a single hot component 108-x is depicted. For the side view, only the hot component 108-x is depicted and the fan pack 102 is lowered to be in front of the hot component 108-x. In the depicted embodiment, the server rack 104 includes a front door 202, which is optional. The server rack 104 also includes a fan pack space 204 for the fan pack 102 to move up and down. In some embodiments, the fan pack space 204 is defined by a frame that includes vertical guides 206, the fan pack 102, etc. and is configured to mount to a standard server rack 104. In other embodiments, the frame is configured to have the front door 202 mounted to the frame. In other embodiments, the frame is configured to mount to a front of the front door 202.

A vertical guide 206 is depicted in the fan pack space 204 and may be connected to the frame. The vertical guide 206 may be a vertical rod, a vertical rail, cables, or other similar mechanism designed to maintain the fan pack 102 in a particular horizontal orientation as the fan pack 102 moves vertically. The particular horizontal orientation, in some embodiments, is where the one or more fans 106 of the fan pack 102 are on a same horizontal plane as components 108 of the server rack 104 and are pointed toward components 108 of the server rack 104 as depicted in the front view. For example, a vertical guide 206 may be a metal rod and each fan pack 102 may include one or more guides around the metal rod and secured to the fan pack and are designed to slide up and down while holding the fan pack 102 in a position with respect to the metal rod.

Where the vertical guides 206 are cables, in some embodiments the cables have enough tension to hold the fan pack 102 in position. In some embodiments, the cables are fixed and the fan pack 102 includes guides that slide over the cables. In other embodiments, the cables are fixed to the fan pack 102 and are part of the vertical drive 112 and move the fan pack 102 up and down while maintaining position of the fan pack 102 with respect to the components 108. The depicted embodiment includes a single vertical guide 206. In other embodiments, an additional vertical guide 206 is included so that there is a vertical guide 206 on each side of the fan pack 102 (e.g. either side of the front of the server rack 104). In other embodiments, each side includes two or more vertical guides 206.

The apparatus 200, in the depicted embodiment, includes a controls space 208 located on top of the server rack 104 that includes one or more of the vertical drive 112, the positioning controller 114, the power source 110, etc. In other embodiments, one or more of the vertical drive 112, the positioning controller 114, the power source 110 are located elsewhere, such as in a rack space. For example, the power source 110 may be a power supply that powers one or more components 108 in addition to the fans 106, vertical drive 112, positioning controller 114, etc. The vertical drive 112 and/or positioning controller 114, in some embodiments, are designed to fit in a rack space, such as a 1U rack space. While the fan pack 102 and controls space 208 are depicted at the top of the server rack 104, in other embodiments, the fan pack 102 and/or controls space 208 are located below the server rack 104. In an embodiment where the vertical drive 112, positioning controller 114, etc. are located in a rack space, the fan pack 102 may be parked in front of the rack space when not in use.

The side view depicts the fan pack 102 in front of the hot component 108-x and lines depict air flow caused by fans 106 of the fan pack 102 moving from in front of the server rack 104, through the fan pack 102, through the hot component 108-x and out the back of the hot component 108-x. Typically, a component 108 includes a front that allows air flow, such as a perforated grate, a wire mesh, etc. In addition, where a rack front door 202 is included, the rack front door 202 includes openings for air flow.

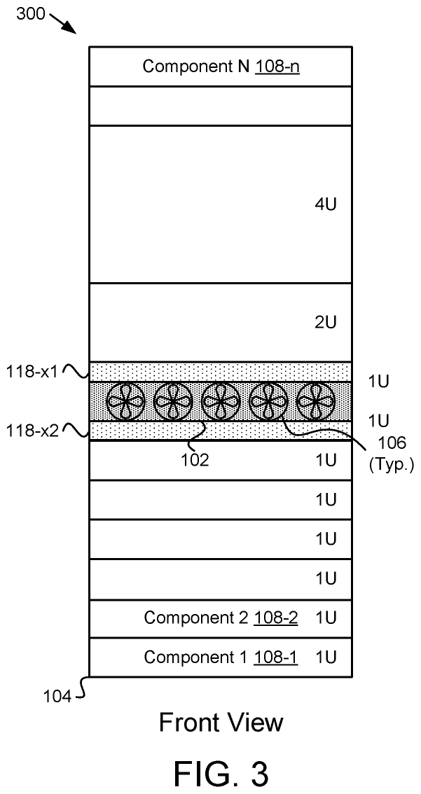

FIG. 3 is a schematic block diagram illustrating a front view of another embodiment of an apparatus 300 for auxiliary cooling redundancy for components using an actuating fan pack 102 positioned between components 108. For example, where there are two hot components 108-x1, 108-x2 that are adjacent and the vertical drive 112 moves the fan pack 102 in increments of one half of a rack unit and the fan pack 102 is positionable between two components (e.g. 108-x1, 108-x2) to provide cooling to both components 108-x1, 108-x2. In some examples, the fan pack 102 includes enough cooling capacity for multiple components 108-x1, 108x2.

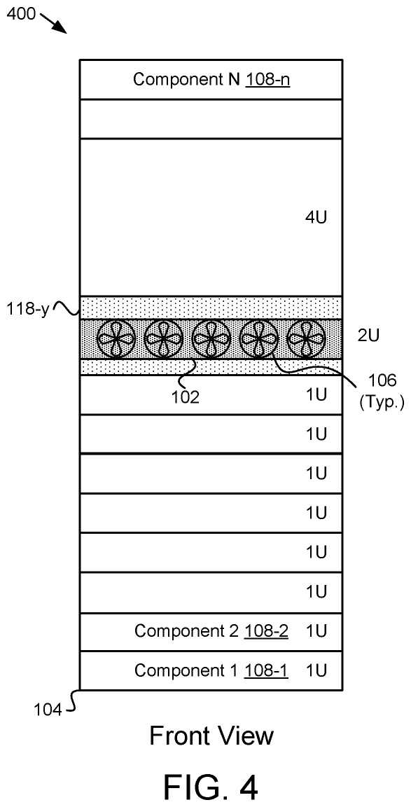

FIG. 4 is a schematic block diagram illustrating a front view of an embodiment of an apparatus 400 for auxiliary cooling redundancy for components using an actuating fan pack 102 positioned to cool a two rack unit component 108-y. In the depicted embodiment, the fan pack 102 may have capacity for more than a 1U component 108 and may be positionable at one half of a rack unit as the apparatus 300 of FIG. 3.

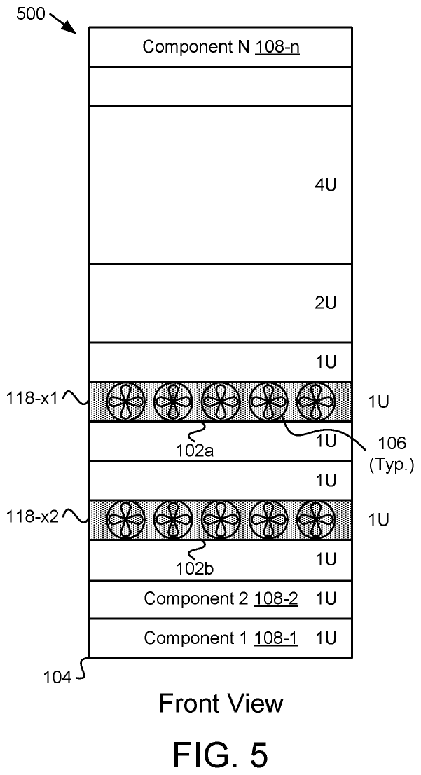

FIG. 5 is a schematic block diagram illustrating a front view of an embodiment of an apparatus 500 for auxiliary cooling redundancy for components with two actuating fan packs 102a, 102b cooling two components 108-x1, 108-x2. Each fan pack 102a, 102b is separately operable to move vertically. In one embodiment, both fan packs 102a, 102b are stored above the server rack 104. In another embodiment, one fan pack 102a is stored above the server rack 104 and the other fan pack 102b is stored at a bottom of the server rack 104. In other embodiments, one or both of the fan packs 102a, 102b are stored on the face of the server rack 104, such as in front of a rack space used for the vertical drive 112, the positioning controller 114, etc. In other embodiments, the apparatus 500 includes three or more fan packs 102a-n.

In one embodiment the vertical drive 112 powers both fan packs 102a, 102b. For example, the vertical drive 112 include two motors, includes components to switch from one pulley system or worm gear to another, etc. In other embodiments, the apparatus 500 includes a separate vertical drive 112 for each fan pack 102a, 102b. In one embodiment, the power source 110 powers both fan packs 102a, 102b, one or more vertical drives 112, etc. In other embodiments, each fan pack 102a, 102b includes a separate power source 110.

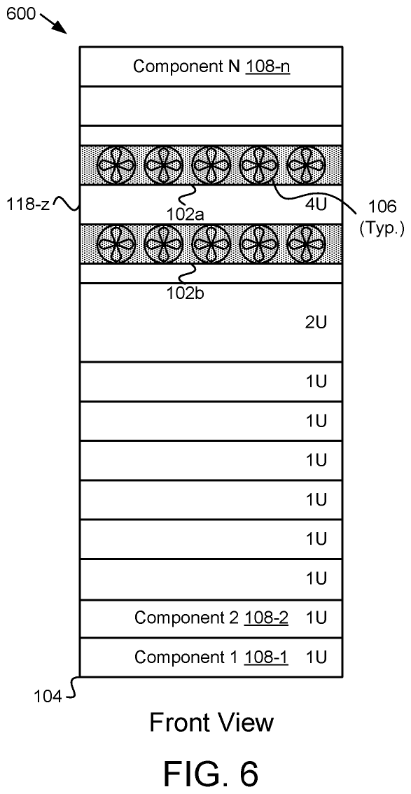

FIG. 6 is a schematic block diagram illustrating a front view of an embodiment of an apparatus 600 for auxiliary cooling redundancy for components using two actuating fan packs 102a, 102b cooling a four rack unit (“4U”) component 108-z. In some embodiments, the apparatus 600 is similar or the same as the apparatus 500 of FIG. 5 and the two fan packs 102a, 102b move to the front of the 4U component 108-z and are spaced appropriately for cooling the 4U component 108-z.

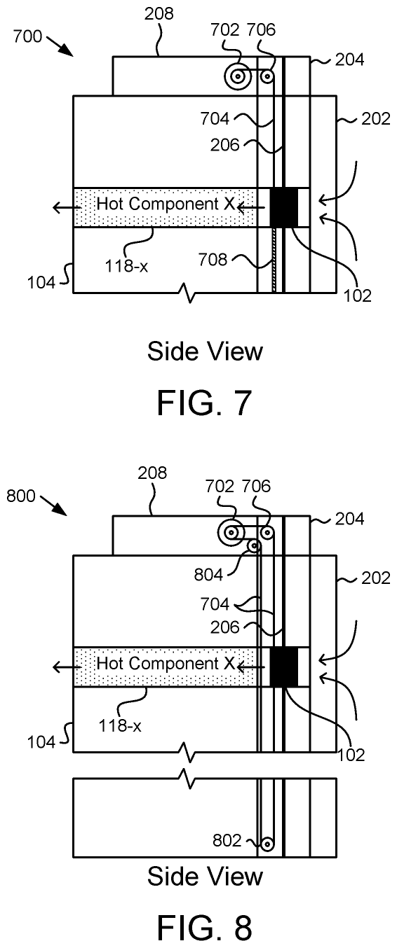

FIG. 7 is a schematic block diagram illustrating a partial side view of an embodiment of an apparatus 700 for auxiliary cooling redundancy for components using an actuating fan pack 102 with a pulley and spring lift system. The apparatus 700 includes a hot component 108-x cooled by a fan pack 102 connected to vertical guide(s) 206. The server rack 104 optionally includes a front door 202 and the server rack 104 includes a fan pack space 204 for the fan pack 102, the vertical guide(s) 206, etc. In some embodiments, the vertical drive 112 includes a motor 702 connected to a cable 704 running over a pulley 706 and connected to the fan pack 102. Operating the motor 702 winds or unwinds the cable 704 on a pulley on the motor 702 to raise and lower the fan pack 102. In some embodiments, the apparatus 700 includes one or more springs 708 positioned to assist the motor 702, cable 704 and pulley 706 in raising and/or lowering the fan pack 102. One of skill in the art will recognize other ways to use a cable 704, pulleys 706 and/or springs 708 to raise and lower the fan pack 102.

FIG. 8 is a schematic block diagram illustrating a partial side view of an embodiment of an apparatus 800 for auxiliary cooling redundancy for components using an actuating fan pack 102 with a pulley lift system. The apparatus 800 includes a hot component 108-x cooled by a fan pack 102 connected to vertical guide(s) 206. The server rack 104 optionally includes a front door 202 and the server rack 104 includes a fan pack space 204 for the fan pack 102, the vertical guide(s) 206, etc. In some embodiments, the vertical drive 112 includes a motor 702 connected to a cable 704 running over a pulley 706 and connected to a top of the fan pack 102. In the depicted embodiment, a cable 704 connects to a bottom of the fan pack 102 and runs down to another pulley 802 and then up to another pulley 804 and loops around a pulley on the motor 702. When the motor 702 rotates, the fan pack 102 moves up or down. One of skill in the art will recognize other ways to use a motor 702, pulleys 706, 802, 804, cables 704, springs 708, etc. to raise and lower a fan pack 102.

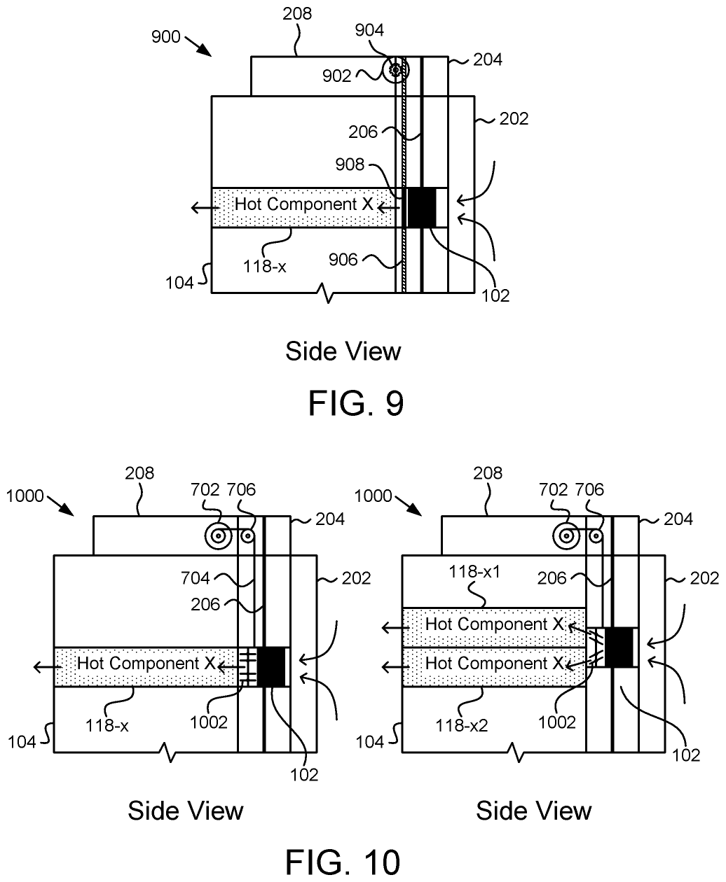

FIG. 9 is a schematic block diagram illustrating a partial side view of an embodiment of an apparatus 900 for auxiliary cooling redundancy for components using an actuating fan pack 102 with a worm gear lift system. The apparatus 900 includes a hot component 108-x cooled by a fan pack 102 connected to vertical guide(s) 206. The server rack 104 optionally includes a front door 202 and the server rack 104 includes a fan pack space 204 for the fan pack 102, the vertical guide(s) 206, etc. In some embodiments, the vertical drive 112 includes a motor 902 with a gear 904 driving a vertically oriented worm gear 906. The worm gear 906 rotates about a vertical axis and an engagement component 908 in the fan pack 102 engages threads in the worm gear to move the fan pack 102 up and down as the worm gear 906 rotates. One of skill in the art will recognize other ways to configure a motor 902, gears 904, a worm gear 906, engagement component 908, etc. to move a fan pack 102 up and down.

FIG. 10 is a schematic block diagram illustrating a partial side view of an embodiment of an apparatus 1000 for auxiliary cooling redundancy for components using an actuating fan pack 102 with louvers 1002 in two different positions. The apparatus 1000 includes one hot component 108-x cooled by a fan pack 102 connected to vertical guide(s) 206 in the diagram on the left. The diagram on the right includes two hot components 108-x1, 108-x2 cooled by the fan pack 102. The server rack 104 optionally includes a front door 202 and the server rack 104 includes a fan pack space 204 for the fan pack 102, the vertical guide(s) 206, etc. In some embodiments, the vertical drive 112 includes a motor 702 connected to a cable 704 running over a pulley 706 and connected to the fan pack 102. Operating the motor 702 winds or unwinds the cable 704 on a pulley on the motor 702 to raise and lower the fan pack 102. Other embodiments with louvers 1002 include a worm gear 906, springs 708, etc.

In the embodiment on the left with a single hot component 108-x, the louvers 1002 are pointed straight ahead to cool the single hot component 108-x. In the embodiment on the right with two adjacent hot components 108-x1, 108-x2, the fan pack 102 is positioned between the components 108-x1, 108-x2 and the louvers 1002 are positioned to spread air from fans 106 of the fan pack 102 to cover both components 108-x1, 108-x2. In other embodiments, the louvers 1002 can be adjusted to cool a 2U component 108-y. In some embodiments, the positioning controller 114 controls the louvers 1002. In other embodiments, another component controls the louvers 1002. One of skill in the art will recognize other forms of louvers 1002 and other ways to configure and use the louvers 1002.

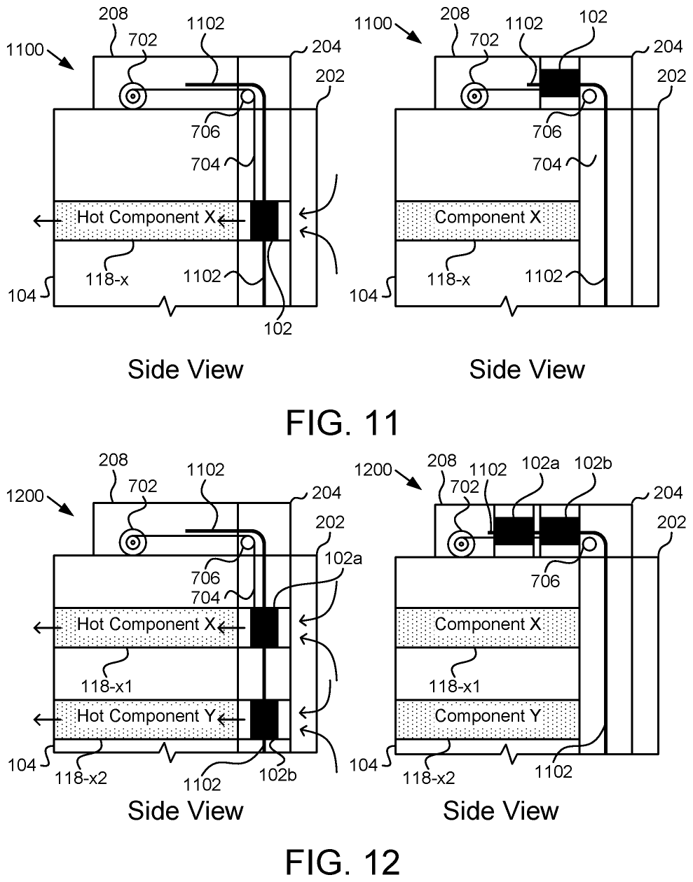

FIG. 11 is a schematic block diagram illustrating a partial side view of an embodiment of an apparatus 1100 for auxiliary cooling redundancy for components using an actuating fan pack 102 in a deployed state and in a retracted state. The server rack 104 optionally includes a front door 202 and the server rack 104 includes a fan pack space 204 for the fan pack 102, the vertical guide(s) 1102, etc. In some embodiments, the vertical drive 112 includes a motor 702 connected to a cable 704 running over a pulley 706 and connected to the fan pack 102. Operating the motor 702 winds or unwinds the cable 704 on a pulley on the motor 702 to raise and lower the fan pack 102. Other embodiments with include a worm gear 906, springs 708, louvers 1002, etc.

The apparatus 1100 includes one hot component 108-x cooled by a fan pack 102 connected to vertical guide(s) 1102 in the diagram on the left. The diagram on the right includes the hot component 108-x but the fan pack 102 is in a stowed position above the server rack 104. In the depicted embodiment, the fan pack 102 rolls around a top edge of the server rack 104 to a position above the server rack 104. For example, the vertical guide 1102 may curve so the fan pack 102 rotates and moves above the server rack 104. In one instance, the vertical guide 1102 includes a track like a garage door and the fan pack 102 includes wheels riding in the track. Other embodiments include a differently configured vertical guide 1102. In addition, while the fan pack 102 is depicted above the server rack 104, in other embodiments, the fan pack 102 retracts to a position below the server rack 104. In addition, in other embodiments, the fan pack 102 does not roll around the server rack 104 but stays vertical. One of skill in the art will recognize other ways to stow the fan pack 102 when not in use.

FIG. 12 is a schematic block diagram illustrating a partial side view of an embodiment of an apparatus 1200 for auxiliary cooling redundancy for components using two actuating fan packs 102a, 102b in a deployed state and in a retracted state. The server rack 104 optionally includes a front door 202 and the server rack 104 includes a fan pack space 204 for the fan packs 102a, 102b, the vertical guide(s) 1102, etc. In some embodiments, the vertical drive 112 includes one or more motors 702 connected to one or more cables 704 running over one or more pulleys 706 and connected to the fan packs 102a, 102b. Operating the motor(s) 702 winds or unwinds the cable(s) 704 on pulley(s) on the motor(s) 702 to raise and lower the fan packs 102a, 102b. Other embodiments with include a worm gear 906, springs 708, louvers 1002, etc.

The apparatus 1200 includes two hot components 108-x1, 108-x2 cooled by two fan packs 102a, 102b connected to vertical guide(s) 1102 in the diagram on the left. In the embodiment, the vertical guide(s) 1102 are similar to the vertical guide(s) 1102 of the apparatus 1100 of FIG. 11. The diagram on the right includes the hot components 108-x1, 108-x2 but the fan packs 102a, 102b are in a stowed position above the server rack 104. In the depicted embodiment, the fan packs 102a, 102b roll around a top edge of the server rack 104 to a position above the server rack 104. In other embodiments, one fan pack 102a is stowed above the server rack 104 and the other fan pack 102b is stowed below the server rack 104. In other embodiments, both fan packs 102a, 102b are stowed below the server rack 104.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus comprising:
a fan pack comprising a fan positioned to provide a stream of air directed toward a component mounted in the server rack, the server rack comprising components for a data system;
a vertical drive configured to move the fan pack vertically to a position so air from the fan is directed toward the component; and
a positioning controller configured to, in response to detecting that a temperature associated with the component exceeds a threshold temperature, control the vertical drive to move the fan pack to a front of a component in the server rack and configured to turn on the fans.

2. The apparatus of claim 1, wherein components mounted in the server rack each have a vertical height that is an integer number of rack units and the fan pack has a vertical height of at least one rack unit (“1U”).

3. The apparatus of claim 1, wherein the fan pack comprises a plurality of fans positioned horizontally across the fan pack.

4. The apparatus of claim 1, wherein the vertical drive comprises one or more vertical guides that are configured to maintain the fan pack in a horizontal orientation on a front of the server rack.

5. The apparatus of claim 1, wherein the vertical drive comprises a motor that is configured to move the fan pack up and/or down to a specified position.

6. The apparatus of claim 1, wherein the vertical drive comprises a pulley, a cable, a worm gear and/or a spring.

7. The apparatus of claim 1, wherein the positioning controller is configured to:
sense an ambient temperature where the server rack is located is above an ambient threshold, a temperature of the component is above a threshold, and/or a cooling fan of the component has reached a maximum cooling capacity; and
based on the sensing, direct the vertical drive to move the fan pack to a position in front of the component and turn on the fan of the fan pack.

8. The apparatus of claim 7, wherein the positioning controller is configured to autonomously move the fan pack and to turn on the fan of the fan pack in response to a heat management algorithm determining that heating of the component is above a threshold.

9. The apparatus of claim 7, wherein the positioning controller is configured to move the fan pack and configured to turn on the fan in response to user input, input from a baseboard management controller and/or input from a data center management system.

10. The apparatus of claim 1, wherein the fan pack comprises a plurality of fan packs, wherein each fan pack is separately operable to move vertically.

11. The apparatus of claim 1, wherein the vertical drive is configured to move the fan pack between two components to provide cooling to both components.

12. The apparatus of claim 1, wherein the fan pack comprises an air direction device that is selectively positionable to control a spread of an air flow from the fan to direct the air flow directly to a component with a height of 1U, spread across a front of a component with a height greater than 1U, and/or spread across a front of two or more components.

13. The apparatus of claim 1, wherein the vertical drive is configurable to position the fan pack above and/or below the server rack during a period of non-use of the fan pack.

14. The apparatus of claim 13, wherein the position above the server rack is a position along a top side of the server rack and the position below the server rack is a position along a bottom side of the server rack.

15. An apparatus comprising:
a fan pack comprising a plurality of fans each positioned to provide a stream of air directed toward a component mounted in the server rack, the server rack comprising components for a data system; and
a vertical drive configured to, in response to detecting that a temperature associated with the component exceeds a threshold temperature, move the fan pack vertically to a position such that the stream of air from the fan is directed toward the component, the vertical drive comprising:
one or more vertical guides coupled to the fan pack, the one or more vertical guides configured to position the fan pack horizontally about a vertical axis in the center of a front of the server rack;
a motor; and
a drive system configured to move the fan pack vertically in response to rotation of the motor.

16. The apparatus of claim 15, wherein the fan pack comprises a first fan pack, the apparatus further comprising:
a second fan pack mounted to the vertical guides; and
a second drive system configured to move the second fan pack vertically in response to rotation of the motor and/or a second motor.

17. The apparatus of claim 15, further comprising a positioning controller, the positioning controller configured to:
sense an ambient temperature where the server rack is located is above an ambient threshold, a temperature of the component is above a threshold, and/or a cooling fan of the component has reached a maximum cooling capacity; and
direct the vertical drive to move the fan pack to a position in front of the component; and
turn on the plurality of fans of the fan pack.

18. A system comprising:
a fan pack comprising a fan positioned to provide a stream of air directed toward a component mounted in the server rack, the server rack comprising components for a data system;
a vertical drive configured to move the fan pack vertically to a position so air from the fan is directed toward the component; and
a positioning controller configured to:
sense an ambient temperature where the server rack is located is above an ambient threshold, a temperature of the component is above a threshold, and/or a cooling fan of the component has reached a maximum cooling capacity;
in response to the sensor unit determining that the component needs additional cooling, control the vertical drive to move the fan pack to a position in front of the component; and
turn on the fan of the fan pack.

19. The system of claim 18, wherein the positioning controller is configured to autonomously move the fan pack and to turn on the fan of the fan pack in response to a heat management algorithm determining that heating of the component is above a threshold.

20. The system of claim 18, wherein the positioning controller is configured to move the fan pack and to turn on the fan in response to user input, input from a baseboard management controller and/or input from a data center management system.
